(19) United States
(12) Patent Application Publication
(10) Pub. No.: US 2017/0076799 A1
(43) Pub. Date: Mar. 16, 2017

(54) SEMICONDUCTOR MEMORY DEVICE

(71) Applicant: KABUSHIKI KAISHA TOSHIBA, Tokyo (JP)

(72) Inventor: Yuzuru NAMAI, Kawasaki Kanagawa (JP)

(21) Appl. No.: 15/175,757

(22) Filed: Jun. 7, 2016

(30) Foreign Application Priority Data
Sep. 11, 2015 (JP) 2015-179998

(51) Int. Cl. G11C 16/04; G11C 16/16; G11C 16/26; G11C 16/10

(52) U.S. Cl. CPC G11C 16/0483; G11C 16/10; G11C 16/16; G11C 16/26

(57) ABSTRACT

A semiconductor memory device includes a first block having a first memory cell and a second block having a second memory cell, first and second word lines respectively connected to the first and second memory cells, first and second select transistors having first ends respectively connected to the first and second word lines, a first circuit configured to apply a voltage to the first word line, and to control a gate voltage of the second select transistor, a second circuit configured to apply a voltage to the second word line, and to control a gate voltage of the first select transistor, first and second wirings respectively connected to second ends of the first and second select transistors, a third circuit configured to apply a voltage to the first wiring, and a fourth circuit configured to apply a voltage to the second wiring.

### CROSS-REFERENCE TO RELATED APPLICATION

This application is based upon and claims the benefit of priority from Japanese Patent Application No. 2015-179998; filed Sep. 11, 2015, the entire contents of which are incorporated herein by reference.

### FIELD

Embodiments described herein relate generally to a semiconductor memory device.

### BACKGROUND

Generally, a NAND flash memory, in which memory cells are arranged in three dimensions, is known as one type of a semiconductor memory device.

### DESCRIPTION OF THE DRAWINGS

FIG. 1 is a block diagram of a semiconductor memory device according to a first embodiment.

FIG. 2 is a block diagram of a memory cell array of the semiconductor memory device according to the first embodiment.

FIG. 3 is a circuit diagram of a cell region in the memory cell array of the semiconductor memory device according to the first embodiment.

FIG. 4 is a circuit diagram of the cell region and an outside WL shunt region in the memory cell array of the semiconductor memory device according to the first embodiment.

FIG. 5 is a circuit diagram of the cell region and an inside WL shunt region in the memory cell array of the semiconductor memory device according to the first embodiment.

FIG. 6 is a plan view illustrating the memory cell array and a row decoder of the semiconductor memory device according to the first embodiment.

FIG. 7 is a plan view illustrating the memory cell array and the row decoder of the semiconductor memory device according to the first embodiment.

FIG. 8 is a sectional view of the semiconductor memory device taken along line VIII-VIII in FIGS. 6 and 7.

FIG. 9 is a sectional view of the semiconductor memory device taken along line IX-IX in FIGS. 6 and 7.

FIG. 10 is a timing chart illustrating a read operation of the semiconductor memory device according to the first embodiment.

FIG. 11 is a timing chart illustrating a write operation of the semiconductor memory device according to the first embodiment.

FIG. 12 is a timing chart illustrating an erase operation of the semiconductor memory device according to the first embodiment.

FIG. 13 is a plan view of a memory cell array of a semiconductor memory device according to a second embodiment.

FIG. 14 is a sectional view of the semiconductor memory device taken along line XIV-XIV in FIG. 13.

FIG. 15 is a sectional view of the semiconductor memory device taken along line XV-XV in FIG. 13.

### DETAILED DESCRIPTION

Embodiments provide a semiconductor memory device with an improved operation speed.

In general, according to one embodiment, there is provided a semiconductor memory device including a first block and a second block, the first block comprising multiple memory cells including a first memory cell and the second block comprising multiple second memory cells including a second memory cell, a first word line and a second word line which are respectively connected to the first memory cell and the second memory cell, a first select transistor and a second select transistor, first ends of which are respectively connected to the first word line and the second word line, a first circuit configured to apply a voltage to the first word line, and to control a gate voltage of the second select transistor, a second circuit configured to apply a voltage to the second word line, and to control a gate voltage of the first select transistor, a first wiring and a second wiring which are respectively connected to second ends of the first select transistor and the second select transistor, a third circuit configured to apply a voltage to the first wiring, and a fourth circuit configured to apply a voltage to the second wiring. In a read, write, or erase operation, when the first block is selected, a first voltage is applied to the first word line, a second voltage applied to the first wiring, the first select transistor turned on, and the second the select transistor turned off.

Hereinafter, embodiments will be described with reference to the accompanying drawings. In the following description, the same reference signs will be given to elements having the same functions and the same configurations. A three-dimensional stacked NAND flash memory, in which memory cells are stacked on top of each other on a semiconductor substrate, will be described as an example.

### [1] First Embodiment

A semiconductor memory device according to a first embodiment includes row decoders on both sides of a memory cell array. One of the row decoders selects a block, and the other row decoder turns on a shunt wiring select transistor corresponding to the selected block.

### [1-1] Configuration

### [1-1-1] Entire Configuration

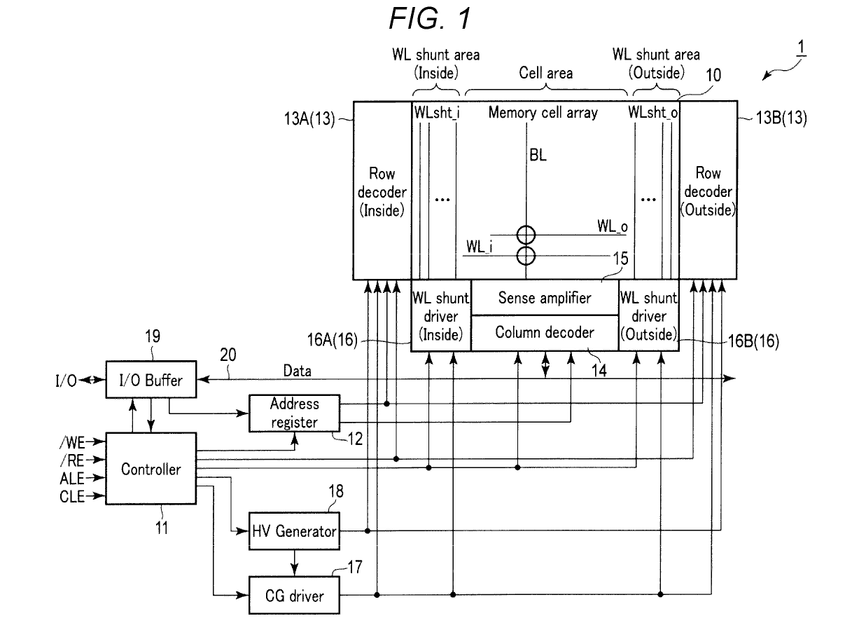

The entire configuration of a semiconductor memory device 1 will be described with reference to FIG. 1. The semiconductor memory device 1 includes a memory cell array 10; a controller 11; an address register 12; a row decoder 13; a column decoder 14; a sense amplifier 15; a WL shunt driver 16; a CG driver 17; a high voltage generator 18; and an input and output buffer 19.

The memory cell array 10 includes a cell region and a WL shunt region. The cell region includes multiple memory cells which are associated with bit lines and word lines. The WL shunt regions are arranged such that the cell region is interposed between the WL shunt regions in a direction parallel to the word lines. The WL shunt region includes shunt wirings of the word lines. In FIG. 1, the WL shunt region positioned on the right side of the cell region is referred to as an outside WL shunt region, and the WL shunt region positioned on the left side of the cell region is referred to as an inside WL shunt region. The shunt wiring in the inside WL shunt region is referred to as a WL shunt wiring WLsht_i, and the shunt wiring in the outside WL shunt region is referred to as a WL shunt wiring WLsht_o. The WL shunt wiring WLsht_i and the WL shunt wiring WLsht_o are used in the following description.

The controller 11 is connected to an external controller (not illustrated) or external host equipment (not illustrated), and receives external control signals. The external control signals include a write enable signal (WE), a read enable signal (RE), an address latch enable signal (ALE), a command latch enable signal (CLE), and the like. The controller 11 controls the entire operation of the semiconductor memory device 1 based on received external control signals, and address information and commands received from the input and output buffer 19.

The address register 12 holds the address information received from the controller 11, and sends the address information to the row decoder 13 and the column decoder 14.

The row decoder 13 decodes the address information received from the address register 12, and selects bit lines based the decoded result. The row decoder 13 applies appropriate voltages to the selected word lines, unselected word lines, and the like. The row decoder 13 includes row decoders 13A and 13B. The row decoders 13A and 13B are arranged such that the memory cell array 10 is interposed between the row decoders 13A and 13B in the direction parallel to the word lines. The row decoder 13A selects a word line WL_i, and the row decoder 13B selects a word line WL_o.

The column decoder 14 decodes the address information received from the address register 12, and sends the decoded address information to the sense amplifier 15.

The sense amplifier 15 is connected to bit lines BL. The sense amplifier 15 senses through the bit lines data read from memory cells during data reading, and transfers write data to the memory cells through the bit lines during data writing according to the address information received from the column decoder 14.

The WL shunt driver 16 applies a voltage to a WL shunt wiring WLsht according to a control signal received from the controller 11. The WL shunt driver 16 includes WL shunt drivers 16A and 16B. The WL shunt driver 16A is connected to the WL shunt wiring WLsht_i, and the WL shunt driver 16B is connected to the WL shunt wiring WLsht_o.

The CG driver 17 generates a voltage required to write or read data according to a control signal received from the controller 11, and supplies the generated voltage to the row decoder 13, the sense amplifier 15, the WL shunt driver 16, and the like.

The high voltage generator 18 generates a voltage required to write or read data according to a control signal received from the controller 11, and supplies the generated voltage to the row decoder 13 and the like.

The input and output buffer 19 is connected to the external controller (not illustrated) or the external host equipment (not illustrated), and exchanges data therewith. Write data is input to the input and output buffer 19 from external equipment, and then is sent to the sense amplifier 15 via a data line 20. Read data read by the sense amplifier 15 is sent to the input and output buffer 19 via the data line 20, and then is output to the external equipment from the input and output buffer 19.

### [1-1-2] Memory Cell Array 10

The configuration of the memory cell array 10 will be described in detail.

### [1-1-2-1] Regarding Circuit Configuration

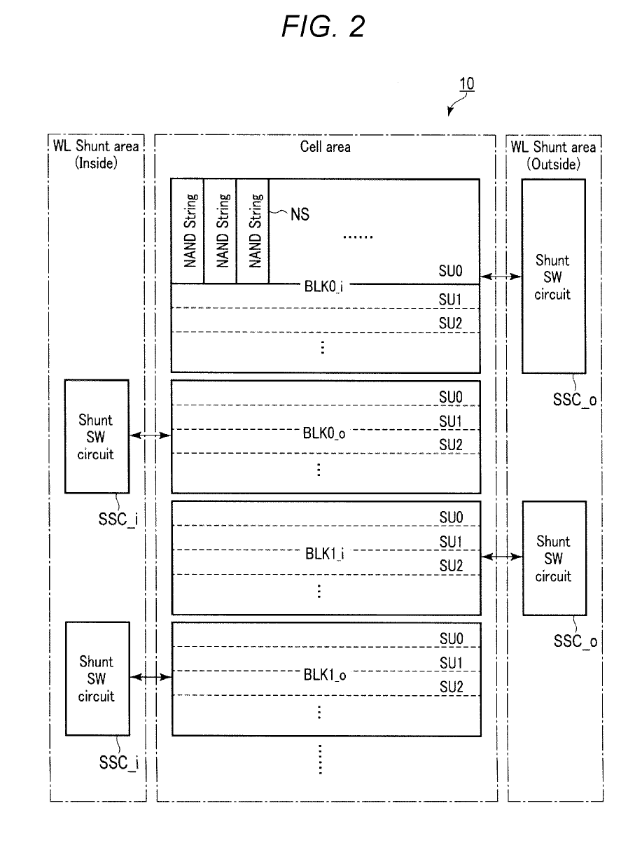

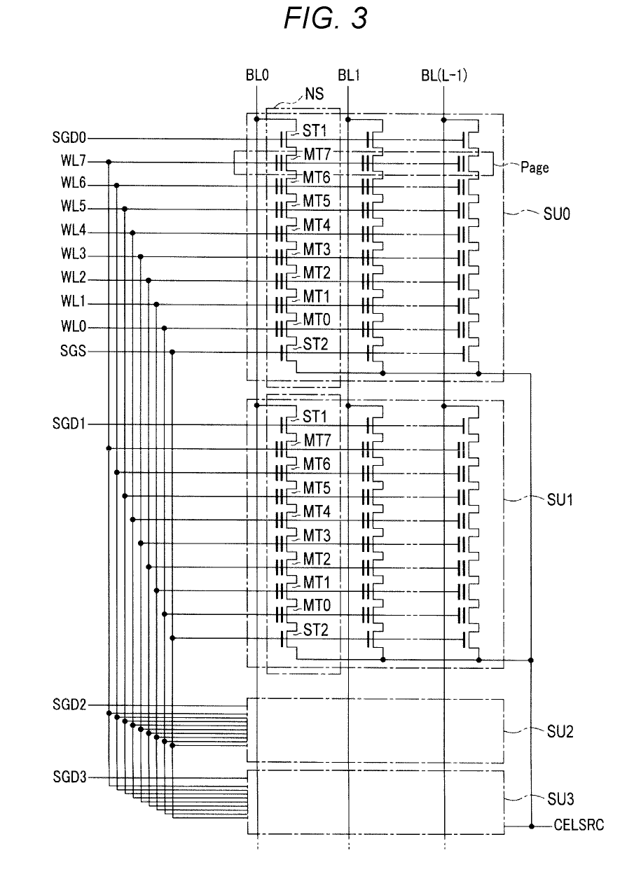

First, the circuit configuration of the cell region will be described with reference to FIGS. 2 and 3. FIG. 2 schematically illustrates the configuration of the cell region.

As illustrated in FIG. 2, the cell region includes multiple blocks BLK, each of which is an aggregate of memory cells. The block BLK is a data erasure unit, and data in the same block BLK are collectively erased. The data erasure unit is not limited to the block BLK, and other erase operations are disclosed in U.S. patent application Ser. No. 13/235,389 entitled “non-volatile semiconductor memory device” filed on Sep. 18, 2011, and in U.S. patent application Ser. No. 12/694,690 entitled “non-volatile semiconductor memory device” filed on Jan. 27, 2010. The entire contents of these patent applications are incorporated in this specification by reference.

Each of the blocks BLK includes multiple string units SU. The string unit SU will be described in detail later. The number of blocks BLK in the memory cell array 10, and the number of string units SU in one block BLK can be set to arbitrary numbers.

The block BLK includes blocks BLK_i (BLK0_i, BLK1_i, . . . ) corresponding to the row decoder 13A, and blocks BLK_o (BLK0_o, BLK1_o, . . . ) corresponding to the row decoder 13B. The blocks BLK_i and the blocks BLK_o are alternately arranged in a direction perpendicular to the word lines WL. The arrangement of the blocks BLK_i and the blocks BLK_o is not limited to that according to the embodiment, and can be changed in various forms.

FIG. 3 is a circuit diagram of one of the blocks BLK. As illustrated, for example, the block BLK includes four string units SU (SU0 to SU3). Each of the string units SU includes multiple NAND strings NS. For example, each of the NAND strings NS includes eight memory cell transistors MT (MT0 to MT7), and select transistors ST1 and ST2.

Each of the memory cell transistors MT includes a control gate and a charge storage layer, and holds data in a non-volatile manner. The memory cell transistors MT0 to MT7 are connected in series to each other.

The select transistor ST1 and the select transistor ST2 are used to select a NAND string NS from which data is read and to which data is written. First ends of the select transistors ST1 and ST2 are respectively connected to an end of the memory cell transistors MT7 and MT0.

Gates of the select transistors ST1 of the string unit SU0 are connected in common to select gate line SGD0. Gates of the select transistors ST1 of the string unit SU1 are connected in common to select gate line SGD1. Gates of the select transistors ST1 of the string unit SU2 are connected in common to select gate line SGD2. Gates of the select transistors ST1 of the string unit SU3 are connected in common to select gate line SGD3. In contrast, gates of the select transistors ST2 in the multiple string units SU are connected in common to the same select gate line SGS. Control gates of the memory cell transistors MT0 to MT7 in the same block BLK are respectively connected in common to word lines WL0 to WL7.

Second ends of the select transistors ST1 of the NAND strings NS in the same column among the NAND strings NS, which are arranged in the memory cell array 10 in a matrix pattern, are connected in common to any one of the bit lines BL (BL0 to BL (L−1)) (where (L−1) is a natural number of one or greater). That is, the bit line BL is connected in common to the corresponding NAND strings NS of the multiple blocks BLK. Second ends of the select transistors ST2 are connected in common to a source line SL. The source line CELSRC is connected in common to the NAND strings NS of the multiple blocks BLK.

Data is collectively written and read for multiple memory cell transistors MT connected to the same word line WL. The unit for the data write and read operation is referred to as a page.

The number of NAND strings NS included in one string unit SU, and the number of memory cell transistors MT included in one NAND string NS are not limited to those numbers in the embodiment, and can be set to arbitrary numbers.

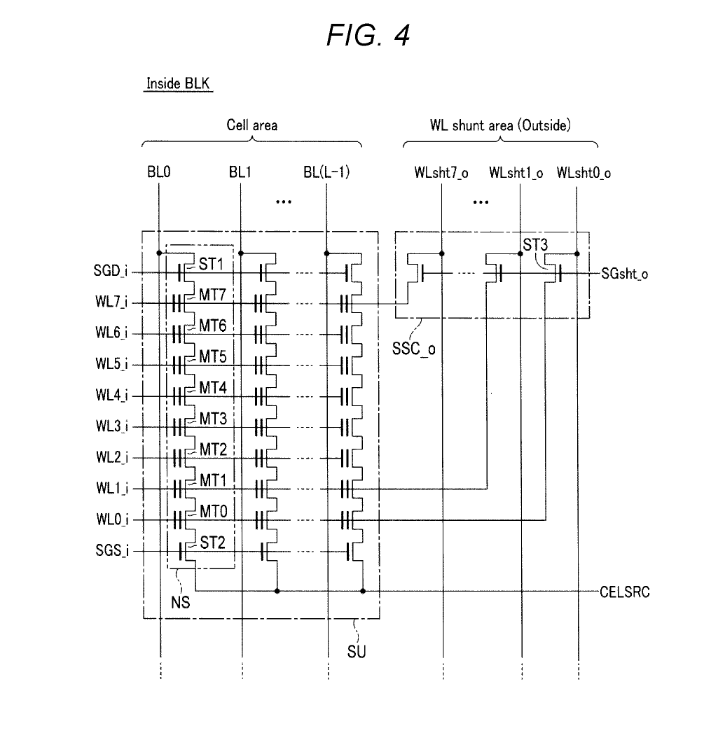

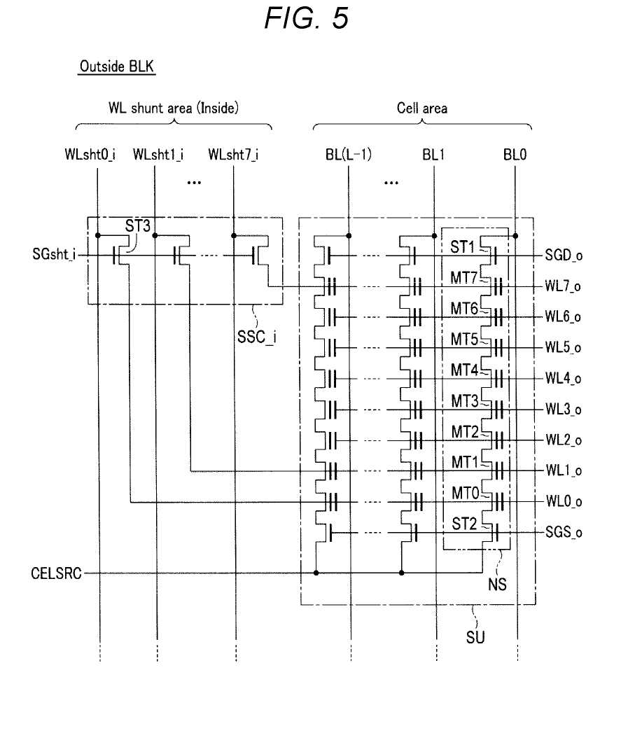

Hereinafter, the configuration of the WL shunt region will be described with reference to FIGS. 2, 4 and 5. FIG. 4 illustrates the circuit diagram of the cell region and the WL shunt region corresponding to the block BLK_i (Inside BLK), and FIG. 5 illustrates the circuit diagram of the cell region and the WL shunt region corresponding to the block BLK_o (Outside BLK).

As illustrated in FIG. 2, the inside WL shunt region includes a shunt switch circuit SSC_i that is provided corresponding to each of the blocks BLK_o, and the outside WL shunt region includes a shunt switch circuit SSC_o that is provided corresponding to each of the blocks BLK_i.

As illustrated in FIG. 4, the outside shunt switch circuit SSC_o includes eight select transistors ST3 which are provided corresponding to word lines WL0_i to WL7_i of the corresponding block BLK_i. First ends of the select transistor ST3 are respectively connected to the word lines WL0_i to WL7_i, second ends thereof are respectively connected to WL shunt wirings WLsht0_o to WLsht7_o, and gates thereof are connected in common to a shunt select line SGsht_o. The potential of the shunt select line SGsht_o is controlled by the row decoder 13 such that the word line WL0_i is electrically connected to the shunt wiring WLsht_o.

Similarly, as illustrated in FIG. 5, the inside shunt switch circuit SSC_i includes eight select transistors ST3 which are provided corresponding to word lines WL0_o to WL7_o of the corresponding block BLK_o. First ends of the select transistor ST3 are respectively connected to the word lines WL0_o to WL7_o, second ends thereof are respectively connected to WL shunt wirings WLsht0_i to WLsht7_i, and gates thereof are connected in common to a shunt select line SGsht_i. The potential of the shunt select line SGsht_i is controlled by the row decoder 13 such that the word line WL0_o is electrically connected to the shunt wiring WLsht_i.

### [1-1-2-2] Regarding Planar Configuration and Sectional Configuration

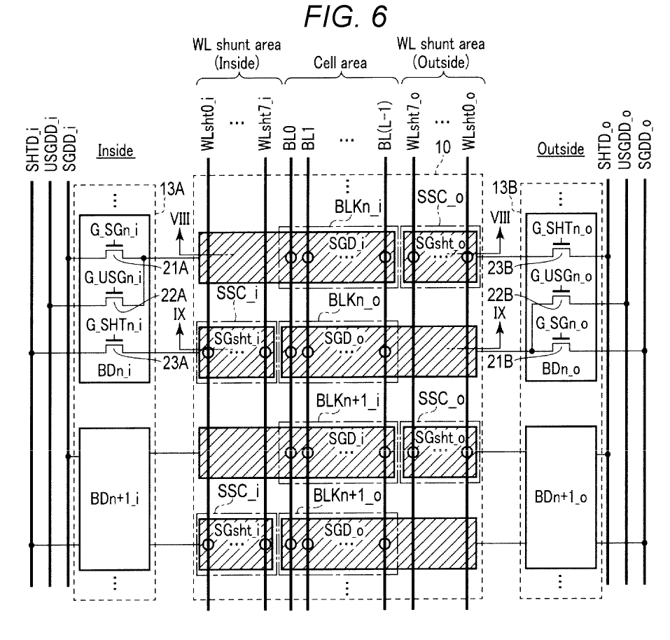

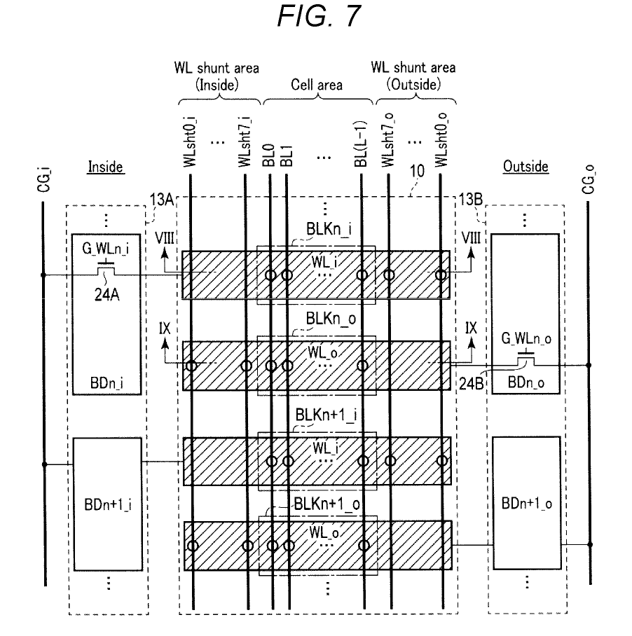

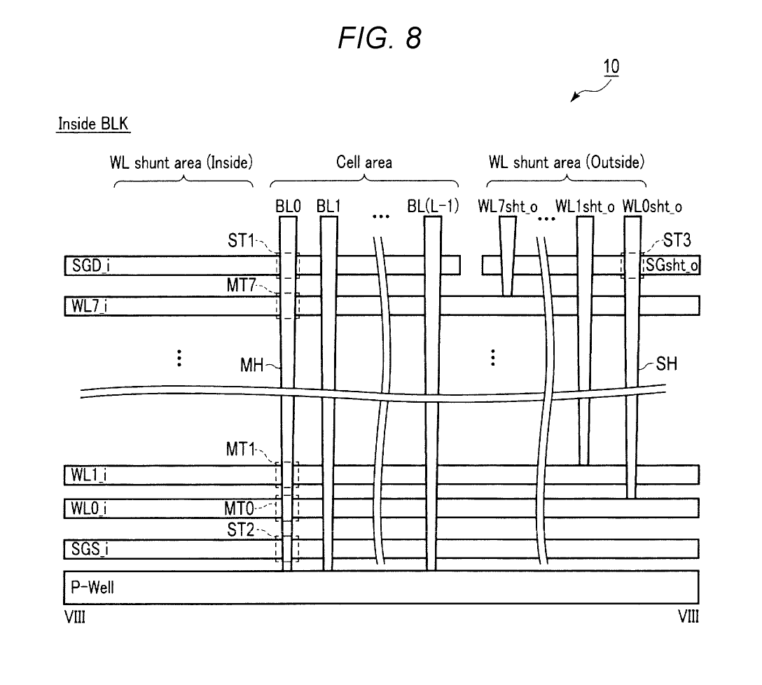

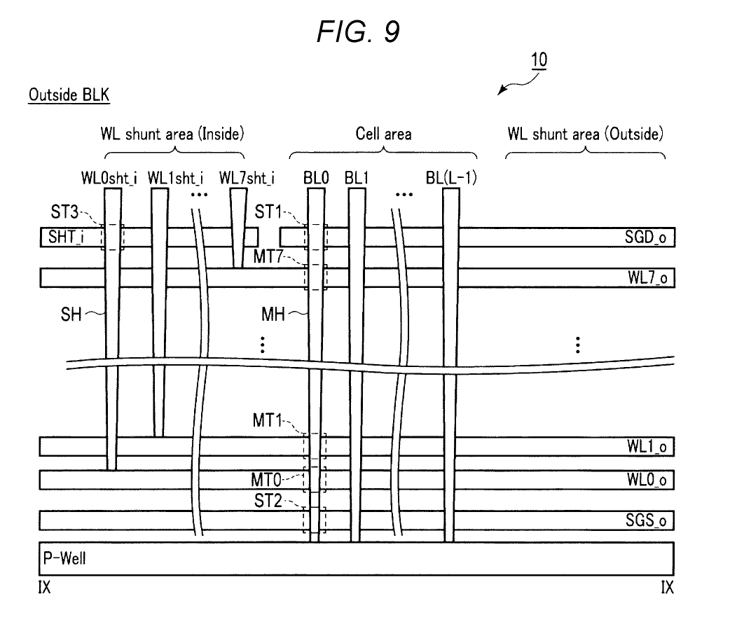

Hereinafter, the planar configuration and the sectional configuration of the memory cell array 10 will be described with reference to FIGS. 6 to 9. FIG. 6 is a plan view illustrating the select gate line SGD and the shunt select line SGsht, and FIG. 7 is a plan view illustrating word lines WL stacked on top of each other. FIG. 8 is a sectional view of the semiconductor memory device 1 taken along line VIII-VIII in FIGS. 6 and 7, and corresponds to a block BLKn_i. FIG. 9 is a sectional view of the semiconductor memory device 1 taken along line IX-IX in FIGS. 6 and 7, and corresponds to a block BLKn_o.

As illustrated, multiple metal wiring layers are formed on a p-type well area of a semiconductor substrate in such a way as to extend from the inside shunt area to the outside shunt area. These metal wiring layers respectively serve as the select gate line SGS, the word lines WL0 to WL7, and the select gate line SGD which are arranged in order from the lowermost layer. The metal wiring layer provided on the word line WL7 is divided between the cell region and the outside WL shunt region in the block BLK_i. A portion of the metal wiring layer in the cell region and the inside WL shunt region serves as the select gate line SGD, and a portion of the metal wiring layer in the outside WL shunt region serves as the shunt select line SGsht_o. In contrast, this metal wiring layer is divided between the cell region and the inside WL shunt region in the block BLK_o. A portion of the metal wiring layer in the cell region and the outside WL shunt region serves as the select gate line SGD, and a portion of the metal wiring layer in the inside WL shunt region serves as the shunt select line SGsht_i.

A memory hole MH is formed in the cell region so as to pass through the metal wiring layers serving as the select gate lines SGD and SGS and the word lines WL, and to reach the p-type well area. A block insulating film, a charge storage layer (insulating film), and a gate insulating film (none of these films are illustrated) are formed on a side surface of the memory hole MH in order. A conductive film (semiconductor pillar) (not illustrated) is embedded into the memory hole MH. The semiconductor pillar serves as the current path of the NAND string NS, and a first end of the semiconductor pillar is connected to the corresponding bit line BL.

Holes SH are provided in the outside WL shunt region of the block BLKn_i so as to respectively reach the word lines WL0_i to WL7_i. Similarly to the cell region, a block insulating film, a charge storage layer (insulating film), and a gate insulating film are formed on an inner side surface of the hole SH in order. A conductive film is embedded into the hole SH. Accordingly, transistors are formed at intersections between the holes SH and the metal wiring layers. Actually, the transistor formed at the intersection between the hole SH and the shunt select line SGsht_o serves as a transistor, that is, serves as the select transistor ST3. Each of transistors formed at intersections between the holes SH and the word lines WL_i has the same configuration as the memory cell transistor MT. Since the number of electrons in the charge storage layer is suppressed to a small number, and the threshold voltage is held at a low value in the transistor, the transistor is always turned on during various operations. Accordingly, the transistors merely serve as current paths. The conductive films in the holes SH are electrically connected to the corresponding word lines WL0_i to WL7_i, and are respectively connected to metal wiring layers (not illustrated) serving as WLsht0_o to WLsht7_o which are provided in layers above the metal wiring layer serving as the shunt select line.

In contrast, these holes SH and these transistors are not provided in the inside WL shunt region of the block BLKn_i.

In contrast, the inside WL shunt region of the block BLKn_o has the same configuration as the outside WL shunt region of the block BLKn_i. That is, the holes SH are provided to respectively reach word lines WL0_o to WL7_o, and transistors are formed at intersections between the holes SH and the metal wiring layers. The transistor formed at the intersection between the hole SH and the shunt select line SGsht_i serves as the select transistor ST3. Other transistors formed at intersections between the holes SH and the word lines WL_o merely serve as current paths. Conductive films in the holes SH are connected to metal wiring layers (not illustrated) serving as WLsht0_i to WLsht7_i.

In contrast, these holes SH and these transistors are not provided in the outside WL shunt region of the block BLKn_o.

In such a configuration, as illustrated in FIGS. 6 and 7, the blocks BLKn_i and BLKn_o are provided in the cell region, and the shunt switch circuits SSC_i and SSC_o are respectively provided in the inside shunt area and the outside shunt area. Each of the bit lines BL0 to BL(L−1) are connected in common to the semiconductor pillar in the corresponding memory hole MH in the same column in the cell region. In the inside WL shunt region, the WL shunt wirings WLsht0_i to WLsht7_i pass above the select gate line SGD_i and the word line WL_i, and each of the WL shunt wirings WLsht0_i to WLsht7_i is connected in common to the semiconductor pillar in the hole SH in the same column. In the outside WL shunt region, the WL shunt wirings WLsht0_o to WLsht7_o pass above the select gate line SGD_o and the word line WL_o, and each of the WL shunt wirings WLsht0_o to WLsht7_o is connected in common to the semiconductor pillar in the hole SH in the same column.

The memory cell array 10 may have other configurations. For example, the configuration of the memory cell array 10 may be as disclosed in U.S. patent application Ser. No. 12/407,403 entitled “three-dimensional stacked non-volatile semiconductor memory” filed on Mar. 19, 2009, in U.S. patent application Ser. No. 12/406,524 entitled “three-dimensional stacked non-volatile semiconductor memory” filed on Mar. 18, 2009, in U.S. patent application Ser. No. 12/679,991 entitled “three-dimensional stacked non-volatile semiconductor memory device and manufacturing method thereof” filed on Mar. 25, 2010, and in U.S. patent application Ser. No. 12/532,030 entitled “semiconductor memory and manufacturing method thereof” filed on Mar. 23, 2009. The entire contents of these patent applications are incorporated in this specification by reference.

### [1-1-3] Row Decoder 13

Hereinafter, the configuration of the row decoder 13 will be described with reference to FIGS. 6 and 7.

As illustrated, the row decoder 13A includes multiple block decoders BDn_i which are provided corresponding to the blocks BLKn_i. The block decoder BDn_i selects the associated block BLKn_i. A block decoder BDn_o included in the row decoder 13B is provided corresponding to the block BLKn_o.

First, the configuration of the block decoder BDn_i will be described. As illustrated in FIGS. 6 and 7, the block decoder BDn_i includes transistors 21A to 24A. A first end of the transistor 21A is connected to a signal line SGDD_i, a second end thereof is connected to the select gate line SGD_i of the block BLKn_i, and a control signal G_SGn_i is input to a gate thereof. A first end of the transistor 22A is connected to a signal line USGDD_i, a second end thereof is connected to the select gate line SGD_i of the block BLKn_i, and a control signal G_USGn_i is input to a gate thereof. A first end of the transistor 23A is connected to a signal line SHTD_i, a second end thereof is connected to the shunt select transistor SGsht_i of the shunt switch circuit SSC_i corresponding to the block BLKn_o, and a control signal G_SHTn_i is input to a gate thereof. A first end of the transistor 24A is connected to a signal line CG_i, a second end thereof is connected to the word line WL_i included in the block BLKn_i, and a control signal G_WLn_i is input to a gate thereof.

Hereinafter, the configuration of the block decoder DBn_o will be described. As illustrated in FIGS. 6 and 7, the block decoder BDn_o includes transistors 21B to 24B. A first end of the transistor 21B is connected to a signal line SGDD_o, a second end thereof is connected to the select gate line SGD_o of the block BLKn_o, and a control signal G_SGn_o is input to a gate thereof. A first end of the transistor 22B is connected to a signal line USGDD_o, a second end thereof is connected to the select gate line SGD_o of the block BLKn_o, and a control signal G_USGn_o is input to a gate thereof. A first end of the transistor 23B is connected to a signal line SHTD_o, a second end thereof is connected to the shunt select transistor SGsht_o of the shunt switch circuit SSC_o corresponding to the block BLKn_i, and a control signal G_SHTn_o is input to a gate thereof. A first end of the transistor 24B is connected to a signal line CG_o, a second end thereof is connected to the word line WL_o included in the block BLKn_o, and a control signal G_WLn_o is input to a gate thereof.

In such a configuration, the transistors 21A to 24A and the transistors 21B to 24B transfer the voltages of the signal lines to the corresponding wirings according to the control signals.

The block decoder BDn_i includes a transistor (not illustrated) corresponding to the select gate line SGS_i, and transfers the voltage of the signal line corresponding to the select gate line SGS_i. The block decoder BDn_o includes a transistor (not illustrated) corresponding to the select gate line SGS_o, and transfers the voltage of the signal line corresponding to the select gate line SGS_o.

The CG driver 17 or the high voltage generator 18 supplies a voltage to each of the signal lines connected to the block decoders BD.

### [1-2] Operation

### [1-2-1] Read Operation

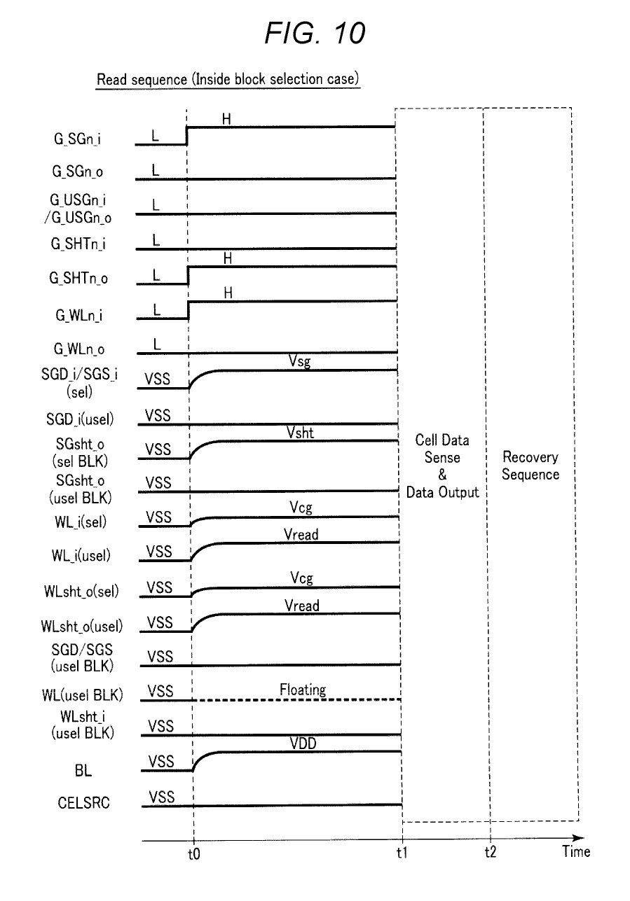

With regard to a read operation of the semiconductor memory device 1, a read operation of a selected block BLKn_i will be exemplarily described with reference to FIG. 10.

At time t0, the semiconductor memory device 1 is operated as follows.

In order to select one string unit SU included in the selected block BLKn_i, the controller 11 sets the control signals G_SGn_i, G_SHTn_o, and G_WLn_i to a logic “H” level, and the control signals G_SG_n_o, G_USGn_i, G_USGn_o, G_SHTn_i, and G_WLn_o to a logic “L” level.

In the selected block BLKn_i, the row decoder 13A applies Vsg to selected select gate lines SGD_i and SGS_i, VSS to an unselected select gate line SGD_i, Vcg to a selected word line WL_i, and Vread to an unselected word line WL_i. Vsg is a voltage at which the select transistors ST1 and ST2 are turned on. VSS is a ground voltage of the semiconductor memory device 1. Vcg is a read voltage used to determine the threshold voltage of the memory cell transistor MT. Vread is a voltage at which the memory cell transistor MT is turned on regardless of the threshold voltage.

The row decoder 13B applies Vsht to the shunt select line SGsht_o corresponding to the selected block BLKn_i, and VSS to an unselected shunt select line SGsht_o corresponding to the selected block BLKn_i. Vsht is a voltage at which the select transistor ST3 is turned on. Accordingly, the select transistor ST3 of the selected block BLKn_i is turned on, and a current path is formed between the WL shunt wiring WLsht_i and the word line WL_o of the selected block BLKn_i.

The WL shunt driver 16B sets the voltage of the WL shunt wiring WLsht_o corresponding to the selected word line WL_i to Vcg, and sets the voltage of the WL shunt wiring WLsht_o corresponding to the unselected word line WL_i to Vread. As such, the voltage applied to the WL shunt wiring WLsht_o is set to the voltage applied to the corresponding word line WL_i.

The row decoder 13 applies VSS to the select gate lines SGD and SGS in an unselected block BLK. Accordingly, the select transistors ST1 and ST2 of the unselected block BLK are turned off, and the current path of the corresponding NAND string NS is set to a floating state. Since the row decoder 13 shut off a current path to the word line WL corresponding to the unselected block BLK, the word line corresponding to the unselected block is set to a floating state.

Since the WL shunt driver 16A does not correspond to the block BLK in which the WL shunt wiring WLsht_i is selected, the WL shunt driver 16A applies VSS to the WL shunt wiring WLsht_i.

The sense amplifier 15 sets the voltage of the bit line BL to VDD by precharging the bit line BL. VDD is the power supply voltage of the semiconductor memory device 1.

The CG driver 17 applies VSS to the source line CELSRC.

At time t1, the sense amplifier 15 senses data stored in the memory cells, and outputs the read data to the input and output buffer 19.

At time t2, the controller 11 brings the semiconductor memory device 1 into a standby state by performing a recovery sequence.

### [1-2-2] Write Operation

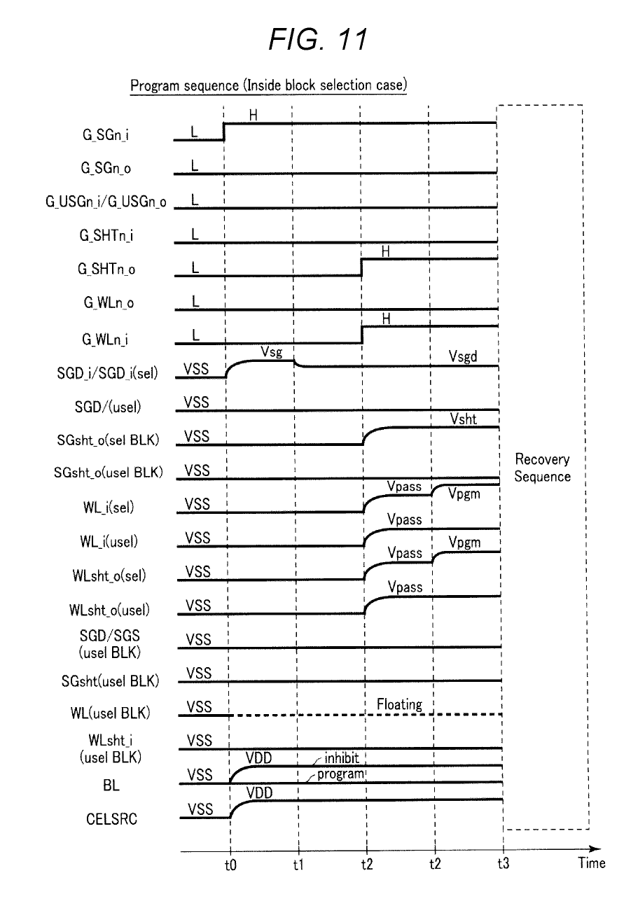

With regard to a write operation of the semiconductor memory device 1, a write operation of a selected block BLKn_i will be exemplarily described with reference to FIG. 11.

At time t0, the semiconductor memory device 1 is operated as follows.

In order to select one string unit SU included in the selected block BLKn_i, the controller 11 sets the control signal G_SGn_i to a logic “H” level, and sets the control signals G_SG_n_o, G_USGn_i, G_USGn_o, G_SHTn_i, G_SHTn_o, G_WLn_i, and G_WLn_o to a logic “L” level.

In the selected block BLKn_i, the row decoder 13A applies Vsg to selected select gate lines SGD_i and SGS_i, and applies VSS to an unselected select gate line SGD_i and an unselected word line WL_i.

The WL shunt driver 16A applies VSS to the WL shunt wiring WLsht_i, and the WL shunt driver 16B applies VSS to the WL shunt wiring WLsht_o.

The sense amplifier 15 applies VSS to a bit line BL which is a write operation target, and applies VDD to a write-prohibited bit line BL.

The CG driver 17 sets the voltage of the source line CELSRC to VDD.

The row decoder 13 is operated to correspond to an unselected block BLK in the same manner as at time t0 in the read operation illustrated in FIG. 10.

At time t1, the row decoder 13A sets the voltages of the selected select gate lines SGD_i and SGS_i to Vsgd. The value of the voltage Vsgd is less than that of Vsg. The amount of current flowing through the select transistor ST1 to which Vsgd is applied is smaller than current flowing through the select transistor ST1 to which Vsg is applied.

At time t2, the controller 11 sets the control signals G_SHTn_o and G_WLn_i to a logic “H” level. The row decoder 13A applies Vpass to a selected word line WL_i and an unselected word line WL_i. Vpass is a voltage at which the memory cell transistor MT is turned on regardless of the threshold voltage. The WL shunt driver 16B applies Vpass to the WL shunt wiring WLsht_o.

At time t3, the row decoder 13A applies Vpgm to the selected word line WL_i. Vpgm is a high voltage at which electrons can be injected into a charge storage layer of the memory cell transistor MT. The WL shunt driver 16B applies Vpass to the WL shunt wiring WLsht_o corresponding to the selected word line WL_i.

At time t4, the controller 11 brings the semiconductor memory device 1 into a standby state by performing a recovery sequence.

As such, in the write operation of the semiconductor memory device 1, the voltage of the WL shunt wiring WLsht_o is set to the voltage applied to the corresponding word line WL_i.

### [1-2-3] Erase Operation

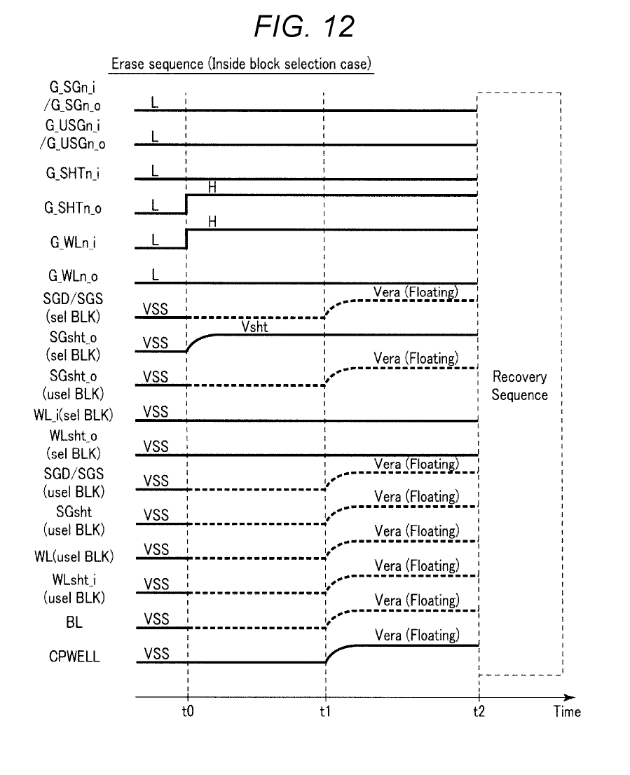

With regard to a write operation of the semiconductor memory device 1, a read operation of a selected block BLKn_i will be exemplarily described with reference to FIG. 12.

At time t0, the semiconductor memory device 1 is operated as follows.

The controller 11 sets the control signal G_SHTn_o and GWLn_i to a logic “H” level, and sets the control signals G_SG_n_i, G_SGn_o, G_USGn_i, G_USGn_o, G_SHTn_i, and G_WLn_o to a logic “L” level. Accordingly, the select gate lines SGD and SGS in the selected block BLKn_i are set to a floating state.

The row decoder 13A applies VSS to the word line WL_i in the selected block BLKn_i.

The WL shunt driver 16B applies VSS to the WL shunt wiring WLsht_o corresponding to the selected block BLKn_i.

The row decoder 13 sets the select gate lines SGD and SGS, the word line WL, and the shunt select line SGsht_i of an unselected block BLK to a floating state.

The sense amplifier 15 sets the bit line BL to a floating state.

The WL shunt driver 16A sets the shunt wiring SGsht_i corresponding to the unselected block BLK to a floating state.

At time t1, the high voltage generator 18 applies Vera to a well line CPWELL. Vera is a high voltage at which electrons held in the charge storage layer of the memory cell transistor MT can be drawn therefrom. At this time, the select gate lines SGD and SGS, the shunt select line SGsht_i, the word line WL corresponding to the unselected block BLK, and the bit line BL are in a floating state, and thus the voltages increases up to Vera along with an increase in the voltage of the well line CPWELL.

When the voltage of the well line CPWELL in the selected block BLKn_i is increased up to Vera, a high potential occurs between the word line WL and the channel, electrons held in the charge storage layer are drawn therefrom, and data is erased. In contrast, since in the unselected block BLK, the select gate lines SGD and SGS, the word line WL, and the shunt select line SGsht_i are in a floating state, a high potential does not occur between the word line WL and the channel, and data is not erased.

At time t2, the controller 11 brings the semiconductor memory device 1 into a standby state by performing a recovery sequence.

As such, in the write operation of the semiconductor memory device 1, the voltage of the WL shunt wiring WLsht_o is set to the voltage applied to the corresponding word line WL_i.

### [1-3] Effects of First Embodiment

If the time constant of the word line WL is large, the operation speed is decreased in a three-dimensional stacked NAND flash memory in which memory cells are stacked on top of each other.

Since the semiconductor memory device 1 according to the first embodiment is provided with the shunt wirings, the time constant of the word line WL is reduced, and the operation speed is improved. Specifically, the row decoders 13 are provided on both sides of the memory cell array 10, and the word line WL is driven via one of the row decoders 13 to select a block BLK. The shunt select line SGsht corresponding to the selected block BLK is driven via the other row decoder 13, and the select transistor ST3 is turned on such that the word line WL is electrically connected to the WL shunt wiring WLsht. The WL shunt wiring WLsht corresponding to the other row decoder 13 is common to the block BLK corresponding to the one row decoder 13.

When the word line WL is driven via the one row decoder, the other row decoder 13 does not drive the shunt select line SGsht corresponding to the unselected block BLK, and cuts off the select transistor ST3 such that the shunting of the word line WL of the unselected block BLK is prevented.

As such, in the semiconductor memory device 1, the WL shunt wiring WLsht is selectively connected to the word lines WL of the selected block BLK via the row decoders 13 provided on both sides of the memory cell array 10, and the word lines WL are driven from both sides. Accordingly, it is possible to reduce the time constant of the word line WL, and to improve the operation speed of the semiconductor memory device 1. Since the shunt wiring provided is common to the blocks BLK in the semiconductor memory device 1, it is possible to suppress an increase in the chip area caused by the provision of the shunt wirings.

With regard to the read, write, and erase operations of the semiconductor memory device 1, the read, write, and erase operations of the selected block BLKn_i are exemplarily described. These operations of the selected block BLKn_o are same as in those of the block BLKn_i except that inside and outside configurations, and operations thereof are reversed.

### [2] Second Embodiment

Hereinafter, a semiconductor memory device according to a second embodiment will be described. Unlike the configuration described in the first embodiment, in the semiconductor memory device 1 according to the embodiment, the select transistor ST3 of a shunt wiring is provided in a first upper wiring layer above the wiring layer in which the corresponding word line WL is formed.

### [2-1] Regarding Planar Configuration and Sectional Configuration of Memory Cell Array 10

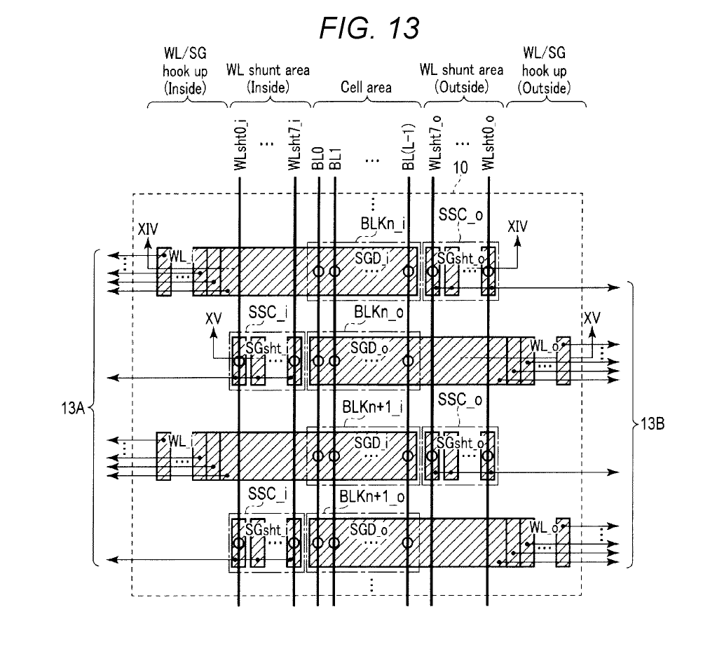

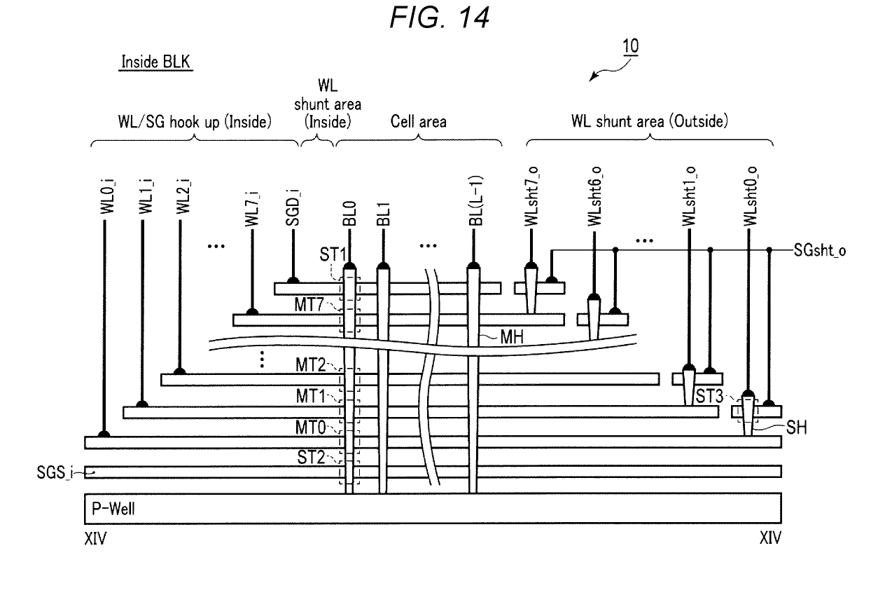

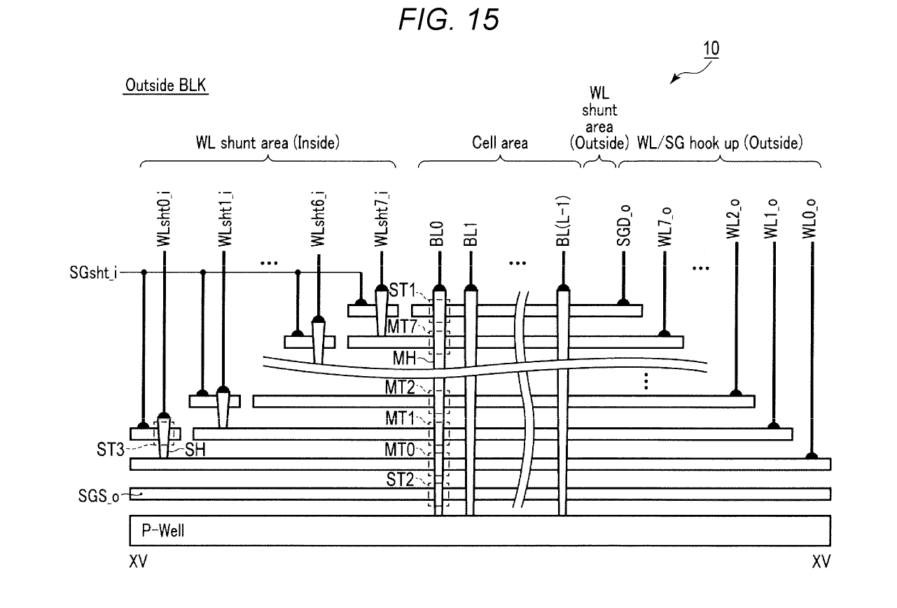

Hereinafter, the planar configuration and the sectional configuration of the memory cell array 10 will be described with reference to FIGS. 13 to 15. FIG. 13 is a plan view illustrating the select gate line SGD, the shunt select line SGsht, and the word line WL. FIG. 14 is a sectional view of the semiconductor memory device 1 taken along line XIV-XIV in FIG. 13, and corresponds to the block BLKn_i. FIG. 15 is a sectional view of the semiconductor memory device 1 taken along line XV-XV in FIG. 13, and corresponds to the block BLKn_o.

A wiring extraction area is not described in the first embodiment; however, the memory cell array 10 includes a wiring extraction area (WL/SGhook up) between the row decoder 13A and the inside WL shunt region, and a wiring extraction area (WL/SGhook up) between the row decoder 13B and the outside shunt area.

As illustrated, metal wiring layers serving as the select gate line SGD and the word lines WL are formed from the WL shunt region to the wiring extraction area. The metal wiring layers are formed such that the lengths of the metal wiring layers are reduced in a direction approaching the cell region as the metal wiring layer is positioned on a further upper side from a lower layer to an upper layer. That is, these metal wiring layers are formed in a step-like shape form in the wiring extraction area. Wirings, extracted from end portions of the metal wiring layers in a stacking direction, are connected to the corresponding row decoder 13.

Similarly to the wiring extraction area, metal wiring layers are formed in a step-like shape in the WL shunt region. Each of the holes SH is provided in a step-like portion so as to pass through a metal wiring layer on top of another, and the holes SH reach the word lines WL0 to WL7, respectively. The metal wiring layer provided above the word line WL0 is divided in the outside WL shunt region of the block BLK_i. A portion of the metal wiring layer in the cell region serves as the word line WL_i or the select gate line SGD_i, and a portion of the metal wiring layer in the outside WL shunt region serves as the shunt select line SGsht_o. Wirings are extracted from end portions of the metal wiring layers serving as the shunt select lines SGsht_o in the stacking direction, and are connected in common to each other.

In contrast, the metal wiring layer is divided in the inside WL shunt region of the block BLK_o. A portion of the metal wiring layer in the cell region serves as the word line WL_o or the select gate line SGD_o, and a portion of the metal wiring layer in the inside WL shunt region serves as the shunt select line SGsht_i. Wirings are extracted from end portions of the metal wiring layers serving as the shunt select lines SGsht_i in the stacking direction, and are connected in common to each other.

That is, a gate electrode of the select transistor ST3 connected to the WL shunt wiring WLsht0 is formed in the same layer as that of the word line WL1. A gate electrode of the select transistor ST3 connected to the WL shunt wiring WLsht7 is formed in the same layer as that of the select gate line SGD.

As such, each of the metal wiring layers serving as the shunt select lines SGsht is formed in a first upper metal wiring layer above the metal wiring layer in which the word line WL (targeted for shunting) is formed. Other portions of the configuration of the second embodiment are the same as those of the first embodiment.

The position where the metal wiring layer serving as the shunt select line SGsht is arranged is not limited to a layer on the metal wiring layer in which the corresponding word line WL is formed, and can be changed in various manners. For example, the metal wiring layer serving as the shunt select line SGsht may be formed in a second upper layer above the metal wiring layer in which the corresponding word line WL is formed. In this case, the hole SH is formed to have the same configuration as that of the memory cell transistor MT such that the hole SH passes through the word lines WL between the gate electrode of the select transistor ST3 and the corresponding word line WL. Similar to the first embodiment, a passing-through portion serves as a current path between the select transistor ST3 and the corresponding word line WL.

The arrangement of the wiring extraction area is not limited to that in the embodiment, and the wiring extraction area may be provided to overlap the WL shunt region.

### [2-2] Effects of Second Embodiment

¥ The same structure as those of the word line WL and the select gate line SGD is applied to a structure in which a wiring is extracted from a wiring layer corresponding to the shunt select line SGsht in the semiconductor memory device 1 according to the second embodiment. In this case, since the distance between a wiring layer in which the gate electrode of the select transistor ST3 is formed and a wiring layer in which the corresponding word line WL is formed is constant, etching can be collectively performed to form all of the holes SH. Accordingly, it is possible to reduce manufacturing steps. As a result, in the semiconductor memory device 1 according to the second embodiment, it is possible to obtain the same effects as those of the first embodiment, and further reduce manufacturing costs of the semiconductor memory device 1 than the first embodiment.

### [3] Others

Each of the semiconductor memory devices according to the aforementioned embodiments includes a first block and a second block <<BLK_i and BLK_o>> (refer to FIG. 6) which respectively include multiple first memory cells and multiple second memory cells; a first word line and a second word line <<WL_i>> (refer to FIG. 7) which are respectively connected to the first memory cell and the second memory cell; a first select transistor and a second select transistor <<ST3>> (refer to FIGS. 4 and 5>>, first ends of which are respectively connected to the first word line and the second word line; a first circuit <<13A>> (refer to FIG. 4) that applies a voltage to the first word line, and controls the gate voltage of the second select transistor; a second circuit <<13B>> (refer to FIG. 4) that applies a voltage to the second word line, and controls the gate voltage of the first select transistor; a first wiring and a second wiring <<WLsht_o and WLsht_i>> (refer to FIGS. 4 and 5) which are respectively connected to second ends of the first select transistor and the second select transistor; and a third circuit and a fourth circuit <<16B and 16A>> (refer to FIG. 1>> which respectively apply voltages to the first wiring and the second wiring. In a read, write, or erase operation, when the first block is selected, a first voltage is applied to the first word line, a second voltage is applied to the first wiring, the first select transistor is turned on, and the second select transistor is turned off.

The first voltage and the second voltage are substantially the same voltage.

The semiconductor memory device further includes a third block <<BLKn+1_i>> (refer to FIG. 6) including multiple third memory cells; a third word line <<WL_i>> (refer to FIG. 7) which is connected to the third memory cell, and applies a voltage to the first circuit; and a third select transistor <<ST3>>, a first end of which is connected to the third word line, a second end of which is connected to the first wiring, and the gate voltage of which is controlled by the second circuit. In the read, write, or erase operation, when the first block is selected, the third select transistor is turned off.

Accordingly, it is possible to improve the operation speed of the semiconductor memory device.

Exemplary embodiments are not limited to the first and second embodiments, and can be modified in various forms. The aforementioned read, write, and erase operations of the semiconductor memory device 1 are exemplarily described, and these operations are not limited to those in the embodiments. In various operations of the embodiments, the points in time in which the controller 11 generates control signals may be offset from each other, and the points in time in which the voltages of various wirings are changed may be offset from each other. In the aforementioned description, the term “connection” represents electrical connection, and also includes connection between components with a separate element interposed therebetween.

In the embodiments, (1) in the read operation, for example, a voltage applied to a word line selected in an A-level read operation is between 0 V and 0.55 V. The applied voltage is not limited to that range, and may be between 0.1 V and 0.24 V, between 0.21 V and 0.31 V, between 0.31 V and 0.4 V, between 0.4 V and 0.5 V, or between 0.5 V and 0.55 V.

For example, a voltage applied to a word line selected in a B-level read operation is between 1.5 V and 2.3 V. The applied voltage is not limited to that range, and may be between 1.65 V and 1.8 V, between 1.8 V and 1.95 V, between 1.95 V and 2.1 V, or between 2.1 V and 2.3 V.

For example, a voltage applied to a word line selected in a C-level read operation is between 3.0 V and 4.0 V. The applied voltage is not limited to that range, and may be between 3.0 V and 3.2 V, between 3.2 V and 3.4 V, between 3.4 V and 3.5 V, between 3.5 V and 3.6 V, or between 3.6 V and 4.0 V.

For example, an amount of time (tR) required for the read operation may be between 25 μs and 38 μs, between 38 μs and 70 μs, or between 70 μs and 80 μs.

(2) The write operation includes the aforementioned program operation and the aforementioned verify operation. In the write operation, for example, an initial voltage applied to a word line selected in the program operation is between 13.7 V and 14.3 V. The applied voltage is not limited to that range, and may be between 13.7 V and 14.0 V or between 14.0 V and 14.6 V.

An initial voltage applied to word lines selected when data is written to odd-numbered word lines may be different from an initial voltage applied to word lines selected when data is written to even-numbered word lines.

For example, when the program operation is performed using an incremental step pulse program (ISPP) method, a step-up voltage is approximately 0.5 V.

For example, a voltage applied to a unselected word line may be between 6.0 V and 7.3 V. The applied voltage is not limited to that range, and may be between 7.3 V and 8.4 V or may be less than or equal to 6.0 V.

An applied path voltage may be changed depending on whether an unselected word line is an odd-numbered word line or an even-numbered word line.

For example, an amount of time (tProg) required for the write operation may be between 1700 μs and 1800 μs, between 1800 μs and 1900 μs, or between 1900 μs and 2000 μs.

(3) For example, in the erase operation, an initial voltage applied to the well, which is formed on the semiconductor substrate, and on which the memory cells are arranged, is between 12 V and 13.6 V. The applied voltage is not limited to that range, and may be between 13.6 V and 14.8 V, between 14.8 V and 19.0 V, between 19.0 V and 19.8 V, or between 19.8 V and 21 V.

For example, an amount of time (tErase) required for the erase operation may be between 3000 μs and 4000 μs, between 4000 μs and 5000 μs, or between 4000 μs and 9000 μs.

(4) The memory cell is structured to include charge storage layers that are arranged on the semiconductor substrate (silicon substrate) with the tunnel insulating film (having a film thickness of 4 nm to 10 nm) interposed therebetween. The charge storage layer may have a structure in which an SiN insulating film or an SiON insulating film with a film thickness of 2 nm to 3 nm is staked on a polysilicon film with a film thickness of 3 nm to 8 nm. Metal such as Ru may be added to polysilicon. An insulating film is provided on the charge storage layer. This insulating film includes a silicon oxide film with a film thickness of 4 nm to 10 nm that is interposed between a lower-layer High-k film with a film thickness of 3 nm to 10 nm and an upper-layer High-k film with a film thickness of 3 nm to 10 nm. The High-k film is made of HfO or the like. The film thickness of the silicon oxide film can be set to be greater than that of the High-k film. A control electrode with a film thickness of 30 nm to 70 nm is formed on the insulating film with a material with a film thickness of 3 nm to 10 nm between the insulating film and the control electrode. The material referred to here is a metal oxide film made of TaO or the like, or a metal nitride film made of TaN or the like. The control electrode can be made of W or the like.

Air gaps can be formed between the memory cells.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first block and a second block, the first block comprising multiple memory cells including a first memory cell and the second block comprising multiple second memory cells including a second memory cell;
a first word line and a second word line which are respectively connected to the first memory cell and the second memory cell;
a first select transistor and a second select transistor, first ends of which are respectively connected to the first word line and the second word line;
a first circuit configured to apply a voltage to the first word line, and to control a gate voltage of the second select transistor;
a second circuit configured to apply a voltage to the second word line, and to control a gate voltage of the first select transistor;
a first wiring and a second wiring which are respectively connected to second ends of the first select transistor and the second select transistor;
a third circuit configured to apply a voltage to the first wiring; and
a fourth circuit configured to apply a voltage to the second wiring,
wherein in a read, write, or erase operation, when the first block is selected, a first voltage is applied to the first word line, a second voltage applied to the first wiring, the first select transistor turned on, and the second the select transistor turned off.

2. The semiconductor memory device according to claim 1,
wherein the first voltage and the second voltage are substantially the same voltage.

3. The semiconductor memory device according to claim 1, further comprising:
a third block including multiple memory cells, including a third memory cell;
a third word line which is connected to the third memory cell; and
a third select transistor, a first end of which is connected to the third word line, a second end of which is connected to the first wiring, and a gate voltage of which is controlled by the second circuit,
wherein in the read, write, or erase operation, when the first block is selected, the third select transistor is turned off.

4. The semiconductor memory device according to claim 3, wherein the first circuit is configured to apply a voltage to the third word line and to control a gate voltage of the third select transistor.

5. The semiconductor memory device according to claim 3,
wherein the first block and the second block are arranged between the first circuit and the second circuit, and
wherein in the read, write, or erase operation, when the first block is selected, the first circuit applies the first voltage to a first end of the first word line, and the second voltage is applied to a second end of the first word line from the third circuit through the first wiring and the first select transistor.

6. The semiconductor memory device according to claim 5,
wherein the first wiring is arranged between the first block and the second circuit, and the second wiring is arranged between the first block and the first circuit.

7. The semiconductor memory device according to claim 1,
wherein the first block includes a third select transistor and a fourth select transistor, and
wherein the memory cells of the first block are stacked between the third select transistor and the fourth select transistor, and gate electrodes of the first select transistor and the fourth select transistor are formed in a same layer above a semiconductor substrate.

8. The semiconductor memory device according to claim 7, further comprising:
a third word line that is formed between the gate electrode of the fourth select transistor and the first word line, and
a conductive pillar passing through the gate electrode of the first select transistor and the third word line, and is in contact with the first word line.

9. The semiconductor memory device according to claim 1,
wherein the first block includes a third select transistor and a fourth select transistor, and
wherein the memory cells of the first block are stacked between the third select transistor and the fourth select transistor, and a gate electrode of the first select transistor is formed in a layer above a semiconductor substrate between a layer in which a gate electrode of the third select transistor is formed and a layer in which a gate electrode of the fourth select transistor is formed.

10. The semiconductor memory device according to claim 9, further comprising:
a third word line that is formed in a first wiring layer between the gate electrode of the fourth select transistor and the first word line,
wherein the first wiring layer is a wiring layer directly above a second wiring layer in which the first word line is formed, and the gate electrode of the first select transistor is formed in the first wiring layer.

11. A semiconductor memory device comprising:
first and second blocks of memory cells, the first block including a first memory cell, and the second block including a second memory cell;
a first word line connected to the first memory cell;
a second word line connected to the second memory cell;
a first circuit including a first transistor, a first end of the first transistor connected to a first signal line and a second end of the first transistor connected to a first end of the first word line, the first circuit controlling the first transistor to transfer a voltage of the first signal line to the first word line;
a second circuit including a second transistor, a first end of the second transistor connected to a second signal line and a second end of the second transistor connected to a first end of the second word line, the second circuit controlling the second transistor to transfer a voltage of the second signal line to the second word line;
a third circuit including a third transistor, a first end of the third transistor connected to a first wiring and a second end of the third transistor connected to a second end of the first word line, the third circuit controlling the third transistor to transfer a voltage of the first wiring to the first word line; and
a fourth circuit including a fourth transistor, a first end of the fourth transistor connected to a second wiring and a second end of the fourth transistor connected to a second end of the second word line, the fourth circuit controlling the fourth transistor to transfer a voltage of the second wiring to the second word line,
wherein the third circuit is between the first block and the second circuit, and the fourth circuit is between the first block and the first circuit.

12. The semiconductor memory device according to claim 11, wherein the first end of the first word line and the second end of the second word line are closer to the second wiring than the first wiring, and the second end of the first word line and the first end of the second word line are closer to the first wiring than the second wiring.

13. The semiconductor memory device according to claim 12, wherein the first and second word lines extend in a first direction and the first and second wirings extend in a second direction crossing the first direction and are connected to the first and second word lines, respectively, through conductive pillars that extend in a third direction that crosses the first and second directions.

14. The semiconductor memory device according to claim 13, wherein the first and second word lines are above a semiconductor substrate in the third direction, and the first word line is between a gate electrode of the third transistor and the semiconductor substrate and the second word line is between a gate electrode of the fourth transistor and the semiconductor substrate.

15. The semiconductor memory device according to claim 13, further comprising:
a third word line above the first word line; and
a fourth word line above the second word line,
wherein a gate electrode of the third transistor is at a same wiring layer as the third word line and a gate electrode of the fourth transistor is at a same wiring layer as the fourth word line.

16. The semiconductor memory device according to claim 11, wherein in a read, write, or erase operation, when the first block is selected, the first and third transistors are turned on, and the second and fourth transistors are turned off.

17. The semiconductor memory device according to claim 11, wherein in a read, write, or erase operation, when the second block is selected, the first and third transistors are turned off, and the second and fourth transistors are turned on.

18. A method of performing an operation in a semiconductor memory device having first and second blocks of memory cells, the first block including a first memory cell, and the second block including a second memory cell, a first word line connected to the first memory cell, and a second word line connected to the second memory cell, said method comprising:
turning on a first transistor to transfer a voltage of a first signal line to the first word line, wherein a first end of the first transistor is connected to the first signal line and a second end of the first transistor is connected to a first end of the first word line;
turning off a second transistor to cut off an electrical connection between a second signal line and the second word line, wherein a first end of the second transistor is connected to the second signal line and a second end of the second transistor is connected to a first end of the second word line;
turning on a third transistor to transfer a voltage of a first wiring to the first word line, wherein a first end of the third transistor is connected to the first wiring and a second end of the third transistor is connected to a second end of the first word line; and
turning off a fourth transistor to cut off an electrical connection between a second wiring and the second word line, wherein a first end of the fourth transistor is connected to the second wiring and a second end of the fourth transistor is connected to a second end of the second word line.

19. The method according to claim 18, wherein another operation is performed by turning off the first and third transistors and turning on the second and fourth transistors.

20. The method according to claim 18, wherein operation includes one of a read operation, a write operation, and an erase operation.
